(19) United States
(12) Patent Application Publication
(10) Pub. No.: US 2025/0031528 A1
(43) Pub. Date: Jan. 23, 2025

(54) DISPLAY DEVICE AND METHOD OF MANUFACTURING THE SAME

(71) Applicant: Japan Display Inc., Tokyo (JP)

(72) Inventor: Ze YUAN, Tokyo (JP)

(73) Assignee: Japan Display Inc., Tokyo (JP)

(21) Appl. No.: 18/765,604

(22) Filed: Jul. 8, 2024

(30) Foreign Application Priority Data
Jul. 20, 2023 (JP) 2023-118553

(51) Int. Cl. H10K 59/122; H10K 59/12

(52) U.S. Cl. CPC H10K 59/122; H10K 59/1201

(57) ABSTRACT

According to one embodiment, a first lower electrode and a second lower electrode separated from each other, a first common layer disposed on the first lower electrode and the second lower electrode, a first light emitting layer disposed on the first common layer and overlapping the first lower electrode in plan view, a second light emitting layer disposed on the first common layer and overlapping the second lower electrode in plan view, a barrier layer disposed on the first common layer between the first light emitting layer and the second light emitting layer, a second common layer disposed on the first light emitting layer, the second light emitting layer, and the barrier layer, and an upper electrode disposed on the second common layer.

### CROSS-REFERENCE TO RELATED APPLICATIONS

This application is based upon and claims the benefit of priority from Japanese Patent Application No. 2023-118553 filed on Jul. 20, 2023, the entire contents of which are incorporated herein by reference.

### FIELD

Embodiments described herein relate generally to a display device and a method of manufacturing the display device.

### BACKGROUND

In recent years, display devices in which organic light emitting diodes (OLEDs), quantum dot light emitting diodes (QLEDs) and the like are applied as display elements have been proposed. These display devices have a common layer formed over multiple pixels. The common layer includes functional layers such as a hole transport layer and the like.

Note here that in the configuration of a display device in which display elements which emit light in colors different from each other are disposed adjacent to each other, carriers (for example, holes) may flow from the emitting display element to the adjacent display element via the common layer. This may cause unintended adjacent display elements to emit light, thereby degrading the display quality in the display device.

### BRIEF DESCRIPTION OF THE DRAWINGS

FIG. 1 is a plan view schematically showing a configuration example of a display device.

FIG. 2 is a diagram showing an example of a layout of subpixels.

FIG. 3 is a cross-sectional view schematically showing the display device taken along line A-A in FIG. 2.

FIG. 4 is a diagram showing an example of the configuration of a display element.

FIG. 5 is an enlarged view schematically showing a section B shown in FIG. 3.

FIG. 6 is a diagram illustrating a processing step in a method of manufacturing the display device.

FIG. 7 is a diagram illustrating a further processing step in the method of manufacturing the display device.

FIG. 8 is a diagram illustrating a still further processing step in the method of manufacturing the display device.

FIG. 9 is a diagram illustrating a still further processing step in the method of manufacturing the display device.

FIG. 10 is a diagram illustrating a still further processing step in the method of manufacturing the display device.

FIG. 11 is a diagram illustrating a still further processing step in the method of manufacturing the display device.

FIG. 12 is a diagram illustrating a still further processing step in the method of manufacturing the display device.

FIG. 13 is a diagram illustrating a still further processing step in the method of manufacturing the display device.

FIG. 14 is a diagram illustrating a still further processing step in the method of manufacturing the display device.

FIG. 15 is a diagram illustrating a still further processing step in the method of manufacturing the display device.

FIG. 16 is a diagram illustrating a still further processing step in the method of manufacturing the display device.

FIG. 17 is a cross-sectional view schematically showing another configuration example of the display device.

### DETAILED DESCRIPTION

In general, according to one embodiment, there is provided a display device comprising a substrate, an insulating layer disposed above the substrate, a first lower electrode and a second lower electrode disposed on the insulating layer and separated from each other, a first common layer disposed on the first lower electrode and the second lower electrode, a first light emitting layer disposed on the first common layer and overlapping the first lower electrode in plan view, a second light emitting layer disposed on the first common layer, overlapping the second lower electrode in plan view, separated from the first light emitting layer, and formed of a material different from that of the first light emitting layer, a barrier layer disposed on the first common layer between the first light emitting layer and the second light emitting layer and surrounding each of the first light emitting layer and the second light emitting layer in plan view, a second common layer disposed on the first light emitting layer, the second light emitting layer, and the barrier layer, and an upper electrode disposed on the second common layer.

According to another embodiment, there is provided a method of manufacturing a display device, comprising forming an insulating layer above a substrate, forming a first lower electrode and a second lower electrode separated from each other, on the insulating layer, forming a rib including a first aperture overlapping the first lower electrode and a second aperture overlapping the second lower electrode in plan view, on the insulating layer, forming a first common layer over the first lower electrode, the second lower electrode, and the rib, forming a first light emitting layer overlapping the first lower electrode in plan view, on the first common layer, forming a second light emitting layer overlapping the second lower electrode in plan view, separated from the first light emitting layer, and made of a material different from that of the first light emitting layer, on the first common layer, forming a barrier layer located on the first common layer between the first light emitting layer and the second light emitting layer and surrounding each of the first light emitting layer and the second light emitting layer in plan view, forming a second common layer over the first light emitting layer, the second light emitting layer, and the barrier layer, and forming an upper electrode on the second common layer.

According to each of the embodiments, it is possible to provide a display device which can suppress degradation in display quality and a method of manufacturing such a display device.

An embodiment will be described hereinafter with reference to the accompanying drawings.

The disclosure is merely an example, and proper changes within the spirit of the invention, which are easily conceivable by a person of ordinary skill in the art, are included in the scope of the invention as a matter of course. To more clarify the explanations, the drawings may pictorially show width, thickness, shape and the like of each portion as compared with actual embodiments, but they are mere examples and do not restrict the interpretation of the invention. In addition, in the specification and drawings, structural elements which function in the same or a similar manner to those described in connection with preceding drawings are denoted by like reference numbers, detailed description thereof being omitted unless necessary.

In the drawings, an X-axis, a Y-axis and a Z-axis orthogonal to each other are provided to facilitate understanding as needed. A direction along the X-axis is referred to as a first direction X, a direction along the Y-axis is referred to as a second direction Y, and a direction along the Z-axis is referred to as a third direction Z. Viewing various elements parallel to the third direction Z is referred to as plan view.

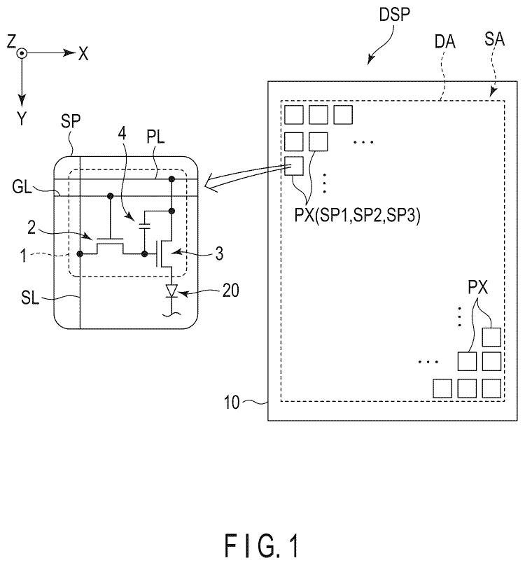

FIG. 1 is a plan view schematically showing a configuration example of a display device DSP. The display device DSP is, for example, an organic electroluminescent display device comprising an organic light emitting diode (OLED) as a display element, and can be mounted on televisions, personal computers, in-vehicle devices, tablet terminals, smartphones, mobile phones, and the like.

The display device DSP includes a display area DA for displaying images and a peripheral area SA surrounding the display area DA. The display area DA comprises a plurality of pixels PX arranged in a matrix along the first direction X and the second direction Y. The pixels PX each comprises a plurality of subpixels SP. For example, the pixel PX contain a red subpixel SP1, a blue subpixel SP2, and a green subpixel SP3. Note that the pixel PX may contain four or more subpixels with some other color such as white in addition to the above-described three-color subpixels.

As shown enlarged in FIG. 1, the subpixel SP comprises a pixel circuit 1 and a display element 20 driven by the pixel circuit 1. The pixel circuit 1 contains a pixel switch 2, a drive transistor 3, and a capacitor 4. The pixel switch 2 and the drive transistor 3 are switching elements each constituted by a thin-film transistor, for example.

In the pixel switch 2, the gate electrode thereof is connected to a respective scanning line GL. One of the source and drain electrodes of the pixel switch 2 is connected to a respective signal line SL, and the other is connected to the gate electrode of drive transistor 3 and the capacitor 4. In the drive transistor 3, one of the source and drain electrodes is connected to a power line PL and the capacitor 4, and the other is connected to the anode of the display element 20. Note here that the configuration of the pixel circuit 1 is not limited to that of the example shown in the figure.

The display element 20 is an organic light emitting diode (OLED) as a light emitting element. For example, the subpixel SP1 comprises a display element 20 that emits light corresponding to red wavelengths, the subpixel SP2 comprises a display element 20 that emits light corresponding to blue wavelengths, and the subpixel SP3 comprises a display element 20 that emits light corresponding to green wavelengths. The configuration of the display element 20 will be described later.

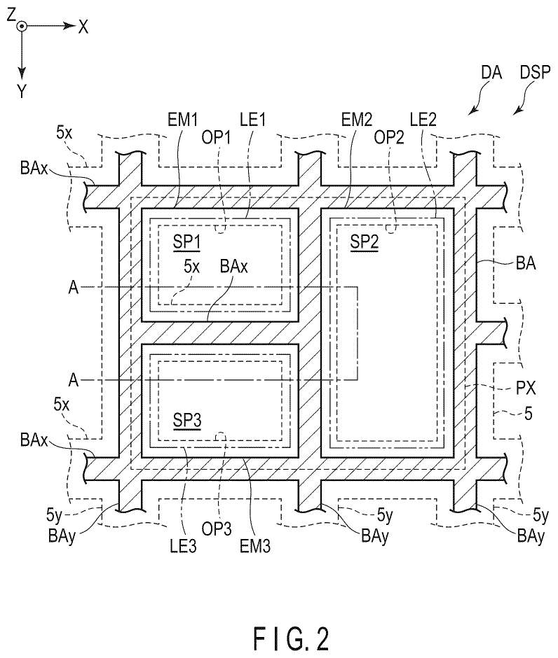

FIG. 2 shows an example layout of a subpixel SP1, a subpixel SP2, and a subpixel SP3. In the example shown in FIG. 2, the subpixel SP1 and the subpixel SP3 are aligned along the second direction Y. Further, the subpixel SP1 and the subpixel SP3 are each aligned with the subpixel SP2 along the first direction X.

When the subpixel SP1, the subpixel SP2, and the subpixel SP3 arranged in the layout shown in FIG. 2, rows in each of which the subpixels SP1 and the subpixels SP3 are arranged alternately along the second direction Y and rows in each of which the plurality of subpixels SP2 are arranged along the second direction Y are formed in the display area DA. These rows are alternately arranged along the first direction X. Note that the layout of the subpixels SP1, subpixels SP2, and subpixels SP3 is not limited to that of the example shown in FIG. 2. For example, the subpixel SP1, subpixel SP2, and subpixel SP3 in each pixel PX may as well be arranged in order along the first direction X.

The display device DSP further comprises a rib 5 shown in dashed lines. The rib 5 includes an aperture OP1, an aperture OP2, and an aperture OP3 in the subpixel SP1, subpixel SP2, and subpixel SP3, respectively. In plan view, the area of each of the aperture OP1 and aperture OP3 is different from the area of the aperture OP2. In the example illustrated in FIG. 2, the area of the aperture OP2 is greater than that of the aperture OP1 and that of the aperture OP3. The area of the aperture OP1 is equal to the area of the aperture OP3. The areas of the aperture OP1, aperture OP2, and aperture OP3 may be different from or all the same as each other.

The rib 5 includes a plurality of ribs 5x extending along the first direction X and a plurality of ribs 5y extending along the second direction Y. The plurality of ribs 5x are each located between each respective pair of the aperture OP1 and aperture OP3 adjacent to each other along the second direction Y and between each respective pair of apertures OP2 adjacent to each other along the second direction Y. The plurality of ribs 5y are each located between each respective pair of the aperture OP1 and aperture OP2 adjacent to each other along the first direction X and between each respective pair of aperture OP2 and aperture OP3 adjacent to each other along the first direction X.

In the example of FIG. 2, the ribs 5x and ribs 5y are connected to each other. With this configuration, the rib 5 is formed into a grid pattern surrounding each of the apertures OP1, apertures OP2, and apertures OP3.

The display device DSP further comprises a lower electrode LE1, a lower electrode LE2, a lower electrode LE3, a light emitting layer EM1, a light emitting layer EM2, and a light emitting layer EM3, and a barrier layer BA. The lower electrode LE1 overlaps the aperture OP1 in plan view. The lower electrode LE2 overlaps the aperture OP2 in plan view. The lower electrode LE3 overlaps the aperture OP3 in plan view. The peripheral portion of each of the lower electrode LE1, lower electrode LE2, and lower electrode LE3 overlap the rib 5 in plan view. The lower electrode LE1, lower electrode LE2, and lower electrode LE3 are arranged to be spaced apart from each other.

The light emitting layer EM1 overlaps the lower electrode LE1 and the aperture OP1 in plan view. The light emitting layer EM2 overlaps the lower electrode LE2 and the aperture OP2 in plan view. The light emitting layer EM3 overlaps the lower electrode LE3 and the aperture OP3 in plan view. The light emitting layer EM1, the light emitting layer EM2, and the light emitting layer EM3 are separated from each other.

The barrier layer BA shown in solid lines includes a plurality of barrier layers BAx extending along the first direction X and a plurality of barrier layers BAy extending along the second direction Y. The plurality of barrier layers BAx are each disposed between each respective pair of light emitting layer EM1 and light emitting layer EM3 adjacent to each other along the second direction Y and between each respective pair of adjacent light emitting layers EM2 adjacent to each other along the second direction Y. The plurality of barrier layers BAy are each disposed between each pair of light emitting layers EM1 and EM2 adjacent to each other along the first direction X and between each pair of light emitting layers EM2 and EM3 adjacent to each other along the first direction X.

The barrier layers BAx are located directly above the ribs 5x, and the barrier layers BAy are located directly above the ribs 5y. In other words, the barrier layer BA is located directly above the rib 5.

In the example illustrated in FIG. 2, the barrier layers BAx and the barrier layers BAy are connected to each other. With this configuration, the barrier layer BA is formed into a grid shape which surrounds each of the light emitting layers EM1, the light emitting layers EM2, and the light emitting layers EM3.

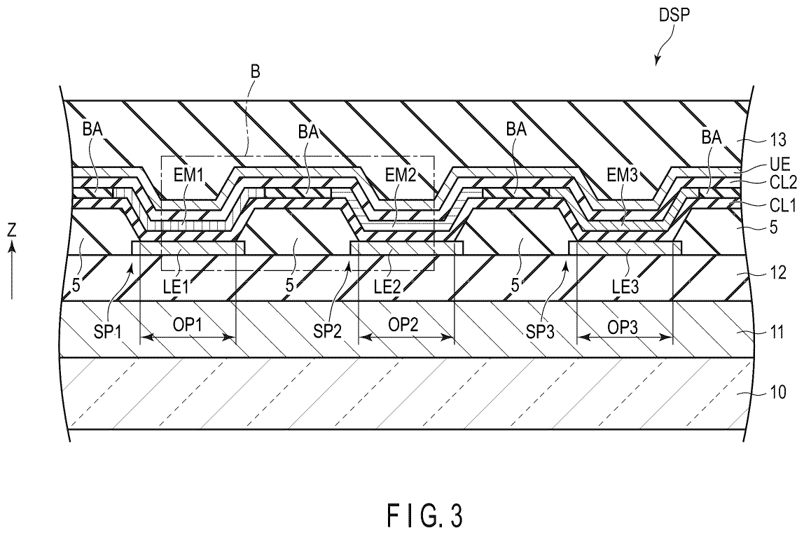

FIG. 3 is a cross-sectional view schematically showing the display device DSP taken along line A-A in FIG. 2.

The display device DSP further comprises a circuit layer 11, an insulating layer 12, a common layer CL1, a common layer CL2, an upper electrode UE, and a sealing layer 13.

The circuit layer 11 is disposed on the substrate 10. The insulating layer 12 is disposed above the substrate 10. The circuit layer 11 is covered by the insulating layer 12. The circuit layer 11 includes various circuits such as the pixel circuit 1 and the like shown in FIG. 1 and various wiring lines such as the scanning lines GL, signal lines SL and power lines PL. The insulating layer 12 includes, for example, an inorganic insulating layer and an organic insulating layer.

The lower electrode LE1, the lower electrode LE2, and the lower electrode LE3 are each disposed on the insulating layer 12. Although omitted in FIG. 3, the lower electrode LE1, the lower electrode LE2, and the lower electrode LE3 are electrically connected to the pixel circuit 1 shown in FIG. 1 via contact holes penetrating the insulating layer 12.

The rib 5 is disposed on the insulating layer 12. The peripheral portion of each of the lower electrode LE1, the lower electrode LE2, and the lower electrode LE3 are covered by the rib 5. The rib 5 is formed, for example, of an organic material.

The common layer CL1 is disposed on the lower electrode LE1, the lower electrode LE2, the lower electrode LE3, and the rib 5. The light emitting layer EM1, the light emitting layer EM2, and the light emitting layer EM3 are disposed on the common layer CL1.

The barrier layer BA is disposed on the common layer CL1 between the light emitting layer EM1, the light emitting layer EM2, and the light emitting layer EM3, respectively. In the example illustrated in FIG. 3, the thickness of the barrier layer BA is equivalent to the respective thicknesses of the light emitting layer EM1, the light emitting layer EM2, and the light emitting layer EM3. The thickness of the barrier layer BA may as well be greater than the respective thicknesses of the light emitting layer EM1, the light emitting layer EM2, and the light emitting layer EM3, or less than the respective thicknesses of the light emitting layer EM1, the light emitting layer EM2, and the light emitting layer EM3.

The common layer CL2 is disposed on the light emitting layer EM1, the light emitting layer EM2, the light emitting layer EM3, and the barrier layer BA. The upper electrode UE is disposed on the common layer CL2. The sealing layer 13 is disposed on the upper electrode UE. The sealing layer 13 includes an organic layer for planarizing the unevenness caused by the rib 5 and an inorganic layer for protecting the light emitting layer EM1, the light emitting layer EM2, and the light emitting layer EM3 from moisture and the like.

The lower electrode LE1, the lower electrode LE2, and the lower electrode LE3 may as well be each formed of a transparent conductive material such as indium tin oxide (ITO) or indium zinc oxide (IZO), or may be formed from a stacked layer of a transparent conductive material and a metal material.

The upper electrode UE is formed of a metal material such as magnesium or silver. Note here that the upper electrode UE may as well be formed of a transparent conductive material such as ITO or IZO.

For example, the lower electrode LE1, the lower electrode LE2, and the lower electrode LE3 correspond to the anode of the display element, and the upper electrode UE corresponds to the cathode of the display element.

The light emitting layer EM1, the light emitting layer EM2, and the light emitting layer EM3 are formed of materials different from each other, respectively. For example, the light emitting layer EM1 is formed of a material which can emit red light, the light emitting layer EM2 is formed of a material which can emit blue light, and the light emitting layer EM3 is formed of a material which can emit green light.

The barrier layer BA is formed, for example, of a material containing silicon-based quantum dots or a silicon-based indirect transition material. As a material which forms the barrier layer BA, it is preferable to adopt a material with extremely small quantum yield, for example. Note that the material of the barrier layer BA is not limited to silicon-based types.

The hole injection barrier of the barrier layer BA is greater than the hole injection barrier of the light emitting layer EM2, which can emit blue light. When the barrier layer BA is disposed between the emitting layer EM1 and the emitting layer EM2, between the emitting layer EM1 and the emitting layer EM3, and between the emitting layer EM2 and the emitting layer EM3, respectively, as shown in FIG. 2, the hole injection barrier of the barrier layer BA is greater than the respective hole injection barriers of the light emitting layer EM1, the light emitting layer EM2, and the light emitting layer EM3.

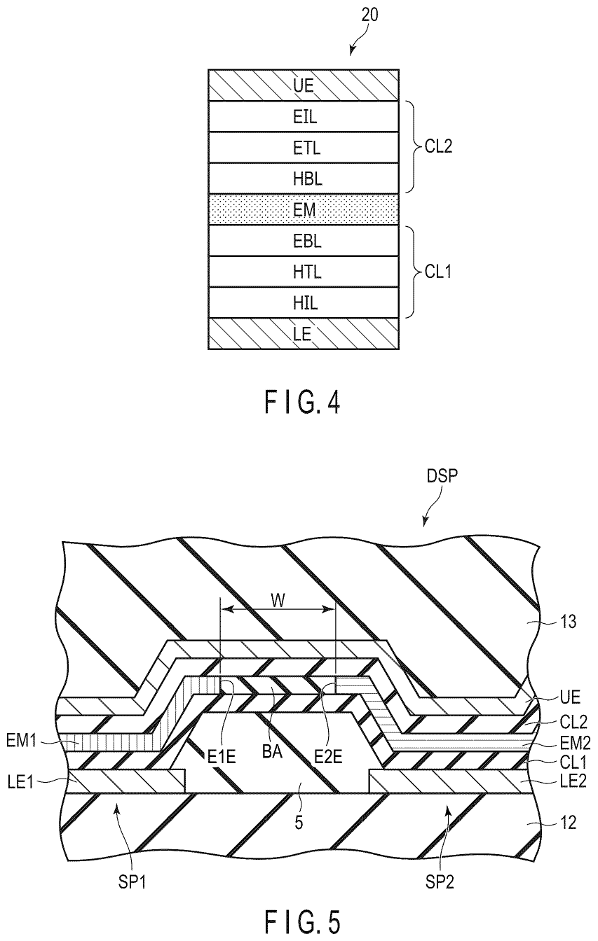

FIG. 4 is a diagram showing an example of a configuration of the display element 20.

The lower electrode LE shown in FIG. 4 corresponds to each of the lower electrode LE1, the lower electrode LE2, and the lower electrode LE3 in FIG. 3. The light emitting layer EM shown in FIG. 4 corresponds to each of the light emitting layer EM1, the light emitting layer EM2, and the light emitting layer EM3 shown in FIG. 3.

For example, the common layer CL1 includes a hole injection layer HIL, a hole transport layer HTL, and an electron blocking layer EBL as functional layers. The hole injection layer HIL is disposed on the lower electrode LE. The hole transport layer HTL is disposed on the hole injection layer HIL. The electron blocking layer EBL is disposed on the hole transport layer HTL. The light emitting layer EM is disposed on the electron blocking layer EBL.

For example, the common layer CL2 includes a hole blocking layer HBL, an electron transport layer ETL, and an electron injection layer EIL as functional layers. The hole blocking layer HBL is disposed on the light emitting layer EM. The electron transport layer ETL is disposed on the hole blocking layer HBL. The electron injection layer EIL is disposed on the electron transport layer ETL. The upper electrode UE is disposed on the electron injection layer EIL.

Note that in addition to the functional layers described above, the common layer CL1 and the common layer CL2 may as well include other functional layers such as a carrier generation layer and the like, if necessary, or at least one of the functional layers described above may be omitted.

FIG. 5 is an enlarged view schematically showing a portion B in FIG. 3. Advantageous effects obtained by the display device DSP of this embodiment will now be explained with reference to FIG. 5. Note that in the following, the case where the light emitting layer EM2 emits light will be explained, but advantageous effects similar to those can be obtained when the light emitting layer EM1 or the light emitting layer EM3 emits light.

First, issues that may arise when the display device DSP does not comprise a barrier layer BA will be explained. Here, the case where the subpixel SP1 does not emit light, whereas the subpixel SP2 emits light will be described. When the light emitting layer EM2 emits light, holes flow from the subpixel SP2 to the subpixel SP1 via the common layer CL1. When the hole injection barrier of the light emitting layer EM1 is smaller than the hole injection barrier of the light emitting layer EM2, the holes flowing into the subpixel SP1 are coupled with electrons injected to the light emitting layer EM1, and thus the vicinity of the end portion E1E of the light emitting layer EM1 emits light. Such undesired emission of light in the light emitting layer EM1 results in poor color mixing, which causes a degradation of display quality.

On the other hand, in this embodiment, the display device DSP comprises a barrier layer BA on the common layer CL1 between the light emitting layer EM1 and the light emitting layer EM2. The light emitting layer EM1 and the light emitting layer EM2 are separated from each other by a width W of the barrier layer BA. With this configuration, when the light emitting layer EM2 emits light, holes flowing via the common layer CL1 and electrons flowing via the common layer CL2 are coupled in the barrier layer BA, which is closer to the light emitting layer EM2 than the light emitting layer EM1 and consumed there. Thus, the number of holes flowing to the subpixel SP1 is reduced. With this configuration, it is possible to suppresses the undesired emission of the light emitting layer EM1, thereby reducing the deterioration of the display quality.

Further, the hole injection barrier of the barrier layer BA is greater than the hole injection barrier of each of the light emitting layer EM1 and the light emitting layer EM2. Therefore, when the light emitting layer EM2 emits light, the probability of carriers coupling in the light emitting layer EM2, which has a hole injection barrier smaller than that of the barrier layer BA, is increased. As a result, the number of carriers flowing to the subpixel SP1 is reduced, thereby making it possible to further suppress the light emission of the light emitting layer EM1. Thus, the degradation of display quality can be further suppressed. Further, by increasing the probability of carrier coupling in the light emitting layer EM2, the light emission efficiency of the light emitting layer EM2 is increased, thereby making it possible to improve the life time of the display element.

Further, the barrier layer BA is formed of a material containing silicon-based quantum dots with a small quantum yield. Therefore, even if carriers are coupled in the barrier layer BA, the barrier layer BA does not substantially emit light. Further, even if the barrier layer BA emits light, the light emission is very weak. Therefore, the coupling of carriers in the barrier layer BA does not substantially affect the display quality of the images displayed on the display device DSP.

Moreover, the barrier layer BA is formed of an indirect transition material. Therefore, when carriers are coupled in the barrier layer BA, they are released as thermal energy. With this heat, the temperature of each of the common layer CL1 and the common layer CL2, which are in contact with the barrier layer BA, arises. As the temperature rises, the resistance of the common layer CL1 and the common layer CL2 increases, and therefore the flow of carriers in the common layer CL1 and the common layer CL2 in the vicinity of the barrier layer BA is restricted. Therefore, when the light emitting layer EM2 emits light, the number of carriers flowing to the subpixel SP1 decreases. As a result, the light emission of the light emitting layer EM1 can be suppressed, thereby making it possible to reduce the display quality.

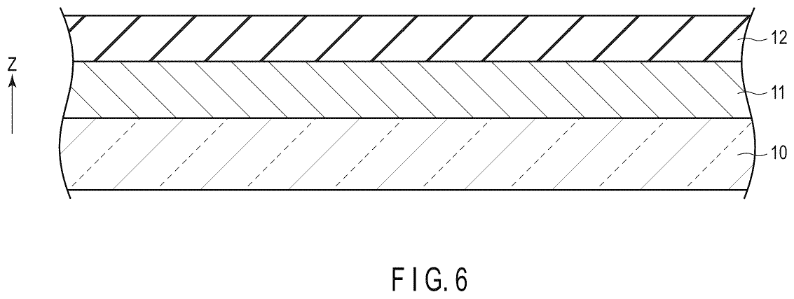

Next, an example of the method of manufacturing the display device DSP will be described. FIGS. 6 to 16 are diagrams illustrating the method of manufacturing the display device DSP.

First, as shown in FIG. 6, an insulating layer 12 is formed above the substrate 10. More specifically, a circuit layer 11 is formed on the substrate 10, and an insulating layer 12 is formed on the circuit layer 11.

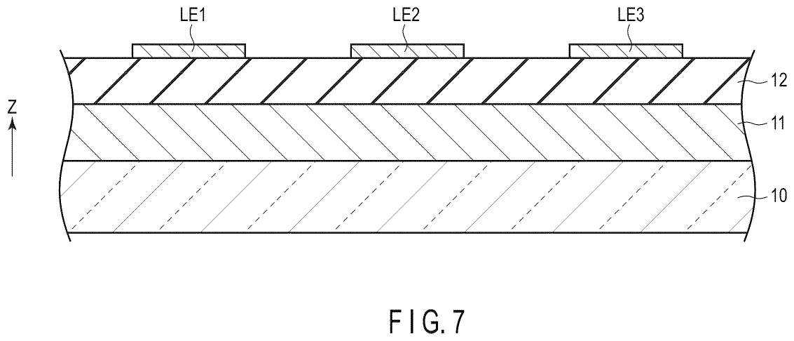

Subsequently, as shown in FIG. 7, a lower electrode LE1, a lower electrode LE2, and a lower electrode LE3 are formed on the insulating layer 12 so as to be separated from each other.

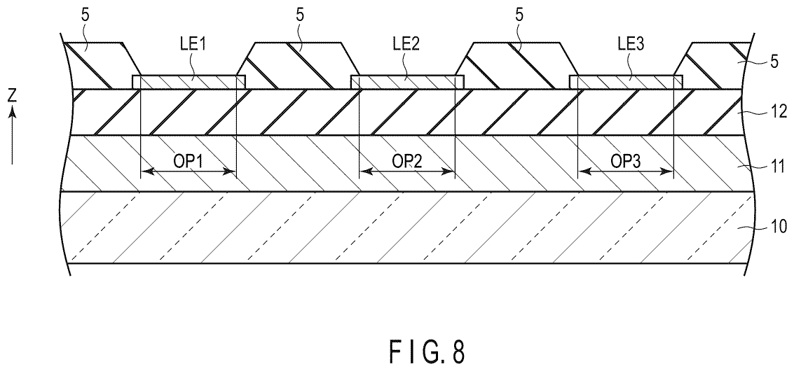

Then, as shown in FIG. 8, a rib 5 is formed on the insulating layer 12. The rib 5 includes an aperture OP1 overlapping the lower electrode LE1, an aperture OP2 overlapping the lower electrode LE2, and an aperture OP3 overlapping the lower electrode LE3 in plan view.

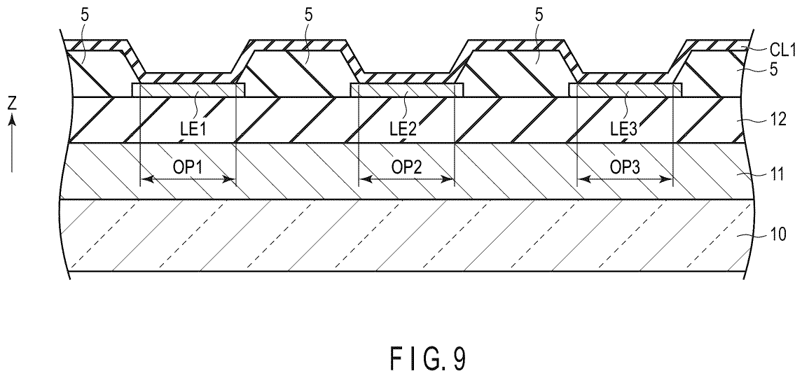

Next, as shown in FIG. 9, a common layer CL1 is formed over the lower electrode LE1, the lower electrode LE2, the lower electrode LE3, and the rib 5. For example, the common layer CL1 includes a hole injection layer, a hole transport layer, and an electron blocking layer as functional layers. The common layer CL1 is brought into contact with the lower electrode LE1 in the aperture OP1, into contact with the lower electrode LE2 in the aperture OP2, and into contact with the lower electrode LE3 in the aperture OP3.

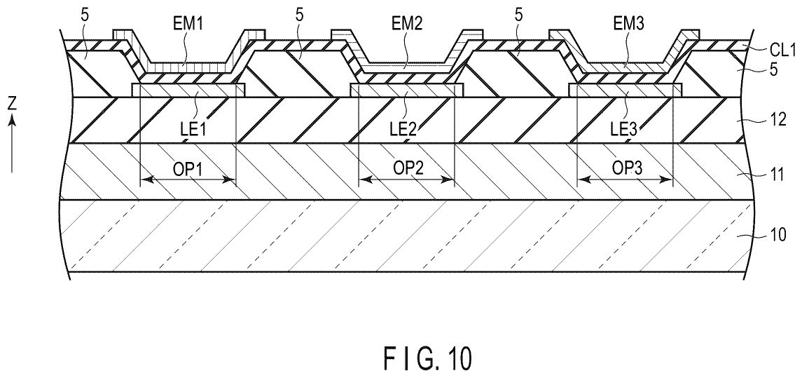

Then, as shown in FIG. 10, a light emitting layer EM1, a light emitting layer EM2, and a light emitting layer EM3 are formed on the common layer CL1 so as to be separated from each other. The light emitting layer EM1 is formed so as to overlap the lower electrode LE1 and the aperture OP1 in plan view. The light emitting layer EM2 is formed so as to overlap the lower electrode LE2 and the aperture OP2 in plan view. The light emitting layer EM3 is formed so as to overlap the lower electrode LE3 and the aperture OP3 in plan view.

The light emitting layer EM1, the light emitting layer EM2, and the light emitting layer EM3 are formed of materials that emit light in wavelength ranges different from each other, respectively. For example, the light emitting layer EM1 is formed of a material which emits red light, the light emitting layer EM2 is formed of a material which emits blue light, and the light emitting layer EM3 is formed of a material which emits green light. The order in which the light emitting layer EM1, the light emitting layer EM2, and the light emitting layer EM3 are formed is not particularly limited.

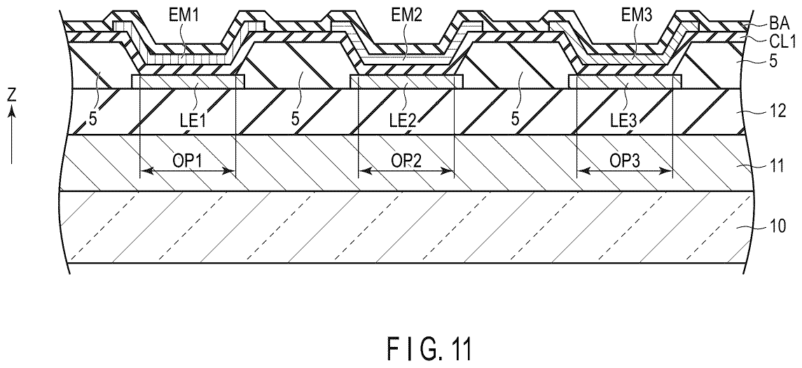

Next, as shown in FIG. 11, a barrier layer BA is formed over the light emitting layer EM1, the light emitting layer EM2, the light emitting layer EM3, and the common layer CL1. More specifically, the material to form the barrier layer BA is applied on the light emitting layer EM1, the light emitting layer EM2, the light emitting layer EM3, and the common layer CL1, and then dried, thus forming the barrier layer BA. For example, an ink-jet method, spin-coating method, printing method, etc., can be used as the method of applying the material. Note that, for example, a material in which the material for forming the barrier layer BA and a photoacid generator are mixed together may be applied by the above-listed method.

As the material to form the barrier layer BA, for example, a material containing silicon-based quantum dots or a silicon-based indirect transition material can be used. As the material for forming the barrier layer BA, for example, a material with extremely small quantum yield is desirable. Note that the barrier layer BA is not limited to the silicon-based materials.

The hole injection barrier of the barrier layer BA is larger than the hole injection barrier of the light emitting layer EM2, which emits blue light. For example, the hole injection barrier of the barrier layer BA is larger than the hole injection barrier of each of the light emitting layer EM1, light emitting layer EM2, and light emitting layer EM3.

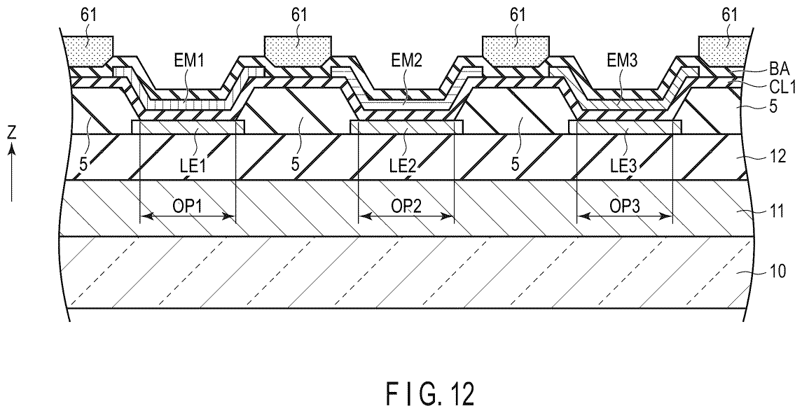

Then, as shown in FIG. 12, a resist 61 is applied over the barrier layer BA and the resist 61 is patterned. In this manner, the resist 61 is formed so as to overlap the barrier layer BA between the light emitting layer EM1, light emitting layer EM2, and light emitting layer EM3, respectively.

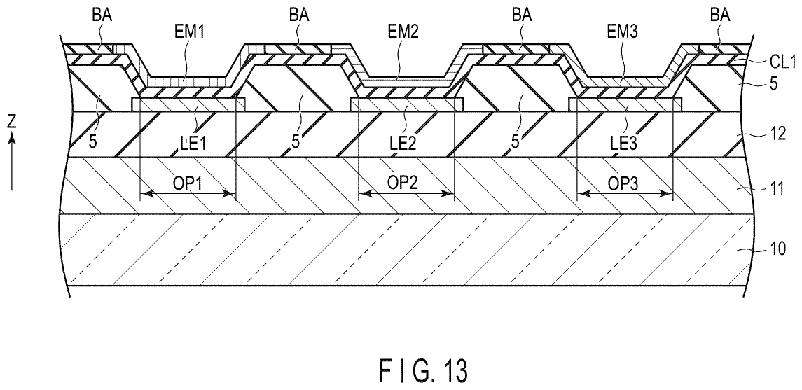

Then, as shown in FIG. 13, the resist 61 shown in FIG. 12 is used as a mask and the barrier layer BA exposed from the resist 61 is removed by etching. After that, the resist 61 is removed. Thus, the barrier layer BA is formed so as to be located on the common layer CL1 between the light emitting layer EM1, light emitting layer EM2, and light emitting layer EM3, respectively, and to surround each of the light emitting layer EM1, light emitting layer EM2, and light emitting layer EM3 in plan view. In the example shown in FIG. 13, the barrier layer BA is formed to have a thickness equivalent to that of the light emitting layer EM1, light emitting layer EM2, and light emitting layer EM3. Note that the barrier layer BA may be formed to have a thickness greater than that of the light emitting layer EM1, light emitting layer EM2, and light emitting layer EM3, or a thickness less than that of the light emitting layer EM1, light emitting layer EM2, and light emitting layer EM3.

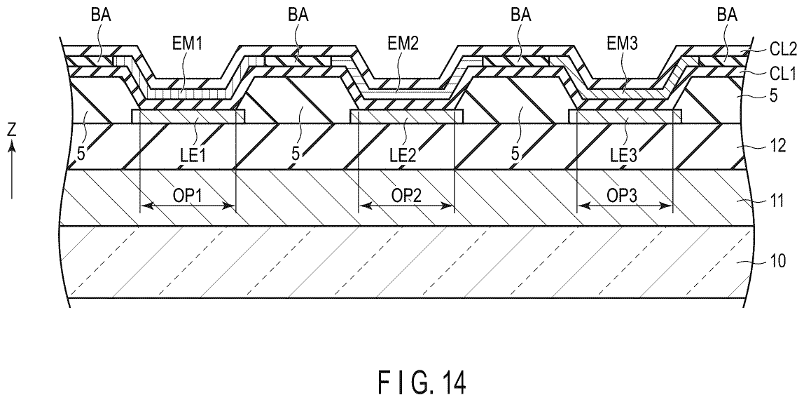

Next, as shown in FIG. 14, a common layer CL2 is formed over the light emitting layer EM1, the light emitting layer EM2, the light emitting layer EM3, and the barrier layer BA. For example, the common layer CL2 includes a hole blocking layer, an electron transport layer, and an electron injection layer as functional layers.

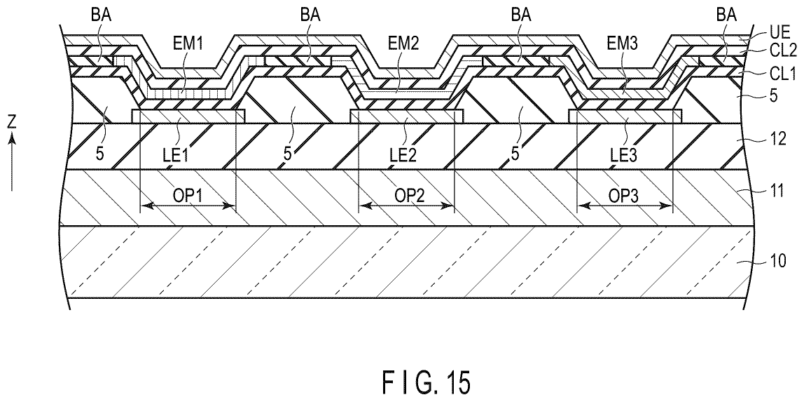

Then, as shown in FIG. 15, an upper electrode UE is formed on the common layer CL2.

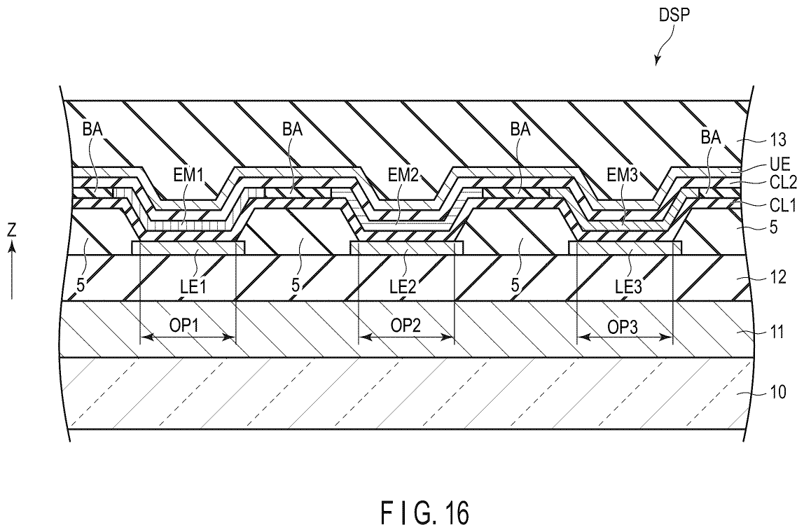

Subsequently, as shown in FIG. 16, a sealing layer 13 is formed on the upper electrode UE.

With the above-described processing steps, the display device DSP of this embodiment is obtained.

Next, another configuration example of the display device DSP will be described. Elements identical or similar to those of the display device DSP described above are marked with the same symbols, and redundant explanations are omitted.

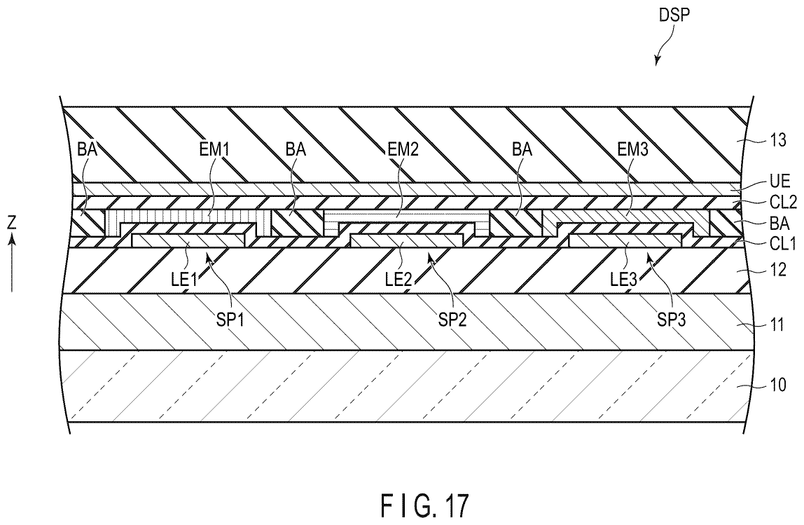

FIG. 17 is a cross-sectional view schematically showing another configuration example of the display device DSP. The display device DSP shown in FIG. 17 comprises, for example, a quantum dot light emitting diode (QLED) as a display element. Further, the display device DSP of FIG. 17 does not comprise an element corresponding to the rib 5 shown in FIG. 3.

The common layer CL1 is disposed on the insulating layer 12. The common layer CL1 covers the lower electrode LE1, the lower electrode LE2, and the lower electrode LE3. In other words, the common layer CL1 is in contact with the insulating layer 12 in a position overlapping the barrier layer BA.

The light emitting layer EM1, the light emitting layer EM2, and the light emitting layer EM3 are formed of a material containing quantum dots. For example, the light emitting layer EM1 is formed of a material containing quantum dots which emit red light, the light emitting layer EM2 is formed of a material containing quantum dots which emit blue light, and the light emitting layer EM3 is formed of a material containing quantum dots which emit green light.

With the display device DSP shown in FIG. 17, advantageous effects similar to those described above can be obtained.

In the above-provided example, the lower electrode LE1 or the lower electrode LE3 corresponds to the first lower electrode, and the lower electrode LE2 corresponds to the second lower electrode. Further, the light emitting layer EM1 or the light emitting layer EM3 corresponds to the first light emitting layer, and the light emitting layer EM2 corresponds to the second light emitting layer. Furthermore, the aperture OP1 or the aperture OP3 corresponds to the first aperture, and the aperture OP2 corresponds to the second aperture. Moreover, the common layer CL1 corresponds to the first common layer, and the common layer CL2 corresponds to the second common layer.

All of the display devices and the methods of manufacturing such display devices that can be implemented by a person of ordinary skill in the art through arbitrary design changes to the display devices and the methods of manufacturing such display devices described above as embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device comprising:
a substrate;
an insulating layer disposed above the substrate;
a first lower electrode and a second lower electrode disposed on the insulating layer and separated from each other;
a first common layer disposed on the first lower electrode and the second lower electrode;
a first light emitting layer disposed on the first common layer and overlapping the first lower electrode in plan view;
a second light emitting layer disposed on the first common layer, overlapping the second lower electrode in plan view, separated from the first light emitting layer, and formed of a material different from that of the first light emitting layer;
a barrier layer disposed on the first common layer between the first light emitting layer and the second light emitting layer and surrounding each of the first light emitting layer and the second light emitting layer in plan view;
a second common layer disposed on the first light emitting layer, the second light emitting layer, and the barrier layer; and
an upper electrode disposed on the second common layer.

2. The display device of claim 1, wherein
the barrier layer is formed of a material containing quantum dots.

3. The display device of claim 2, wherein
the barrier layer is formed of a material containing an indirect transition material.

4. The display device of claim 3, wherein
the indirect transition material contains silicon.

5. The display device of claim 4, wherein
a hole injection barrier of the barrier layer is larger than a hole injection barrier of each of the first light emitting layer and the second light emitting layer.

6. The display device of claim 1, wherein
a thickness of the barrier layer is equal to a thickness of each of the first light emitting layer and the second light emitting layer.

7. The display device of claim 1, wherein
the first common layer includes a hole injection layer, a hole transport layer, and an electron blocking layer, and
the second common layer includes a hole blocking layer, an electron transport layer, and an electron injection layer.

8. The display device of claim 1, further comprising:
a rib disposed on the insulating layer and including a first aperture overlapping the first lower electrode and a second aperture overlapping the second lower electrode in plan view,
wherein
the first common layer is disposed on the rib, and
the barrier layer is located directly above the rib.

9. The display device of claim 8, wherein
in plan view, an area of the first aperture is different from an area of the second aperture.

10. The display device of claim 8, wherein
the first light emitting layer is formed of a material which emits red or green light, and
the second light emitting layer is formed of a material which emits blue light.

11. The display device of claim 1, wherein
the first light emitting layer and the second light emitting layer are formed of a material containing quantum dots.

12. The display device of claim 11, wherein
the first common layer is in contact with the insulating layer at a position overlapping the barrier layer.

13. A method of manufacturing a display device, comprising:
forming an insulating layer above a substrate;
forming a first lower electrode and a second lower electrode separated from each other, on the insulating layer;
forming a rib including a first aperture overlapping the first lower electrode and a second aperture overlapping the second lower electrode in plan view, on the insulating layer;
forming a first common layer over the first lower electrode, the second lower electrode, and the rib;
forming a first light emitting layer overlapping the first lower electrode in plan view, on the first common layer;
forming a second light emitting layer overlapping the second lower electrode in plan view, separated from the first light emitting layer, and made of a material different from that of the first light emitting layer, on the first common layer;
forming a barrier layer located on the first common layer between the first light emitting layer and the second light emitting layer and surrounding each of the first light emitting layer and the second light emitting layer in plan view;
forming a second common layer over the first light emitting layer, the second light emitting layer, and the barrier layer; and
forming an upper electrode on the second common layer.

14. The method of claim 13, wherein
the barrier layer is formed of a material containing quantum dots.

15. The method of claim 14, wherein
the barrier layer is formed of a material containing an indirect transition material.

16. The method of claim 15, wherein
the indirect transition material contains silicon.

17. The method of claim 16, wherein
a hole injection barrier of the barrier layer is larger than a hole injection barrier of each of the first light emitting layer and the second light emitting layer.

18. The method of claim 13, wherein
the first common layer includes a hole injection layer, a hole transport layer, and an electron blocking layer, and
the second common layer includes a hole blocking layer, an electron transport layer, and an electron injection layer.

19. The method of claim 13, wherein
the first light emitting layer is formed of a material which emits red or green light, and
the second light emitting layer is formed of a material which emits blue light.

20. The method of claim 13, wherein
the forming the barrier layer further comprising:
forming the barrier layer over the first light emitting layer, the second light emitting layer, and the first common layer;
forming a resist overlapping the barrier layer between the first light emitting layer and the second light emitting layer; and
removing the barrier layer exposed from the resist by etching using the resist as a mask.
